(19) United States
(12) Patent Application Publication
(10) Pub. No.: US 2026/0173591 A1
(43) Pub. Date: Jun. 18, 2026

(54) HORIZONTAL LIGHT-EMITTING DIODE AND MANUFACTURING METHOD THEREOF

(71) Applicant: Taiwan-Asia Semiconductor Corporation, Hsinchu City (TW)

(72) Inventors: Hong-Ta Cheng, Hsinchu City (TW); Ching-Yuan Tsai, Hsinchu City (TW); Yu-Tong Hsiao, Hsinchu City (TW)

(21) Appl. No.: 19/213,356

(22) Filed: May 20, 2025

(30) Foreign Application Priority Data
Dec. 16, 2024 (TW) 113148848

(51) Int. Cl. H10H 20/831; H10H 20/01; H10H 20/824

(52) U.S. Cl. CPC H10H 20/8312; H10H 20/013; H10H 20/824

(57) ABSTRACT

A horizontal LED and its manufacturing method are provided. The horizontal LED comprises a permanent substrate, an epitaxial composite layer, a transparent conductive layer, multiple conductive plugs, a first conductive type electrode, and a second conductive type electrode. The epitaxial composite layer includes a light-emitting layer with an emission wavelength of 1100 to 2000 nanometers disposed on the permanent substrate. The transparent conductive layer is sandwiched between the permanent substrate and the epitaxial composite layer. Each conductive plug is disposed between the transparent conductive layer and the epitaxial composite layer and is electrically connected to the epitaxial composite layer. The first conductive type electrode is disposed on the permanent substrate, the second conductive type electrode is disposed on the epitaxial composite layer and both are electrically connected to the epitaxial composite layer. Both electrodes are located on the same side of the permanent substrate.

### CROSS-REFERENCES TO RELATED APPLICATIONS

This application claims the benefit of priority to Taiwanese Patent Application No. 113148848 filed on Dec. 16, 2024, which is hereby incorporated by reference in its entirety.

### BACKGROUND OF THE INVENTION

### Field of the Invention

The present invention relates to a horizontal light-emitting diode (LED) and a manufacturing method thereof, and in particular to a horizontal short-wave infrared light-emitting diode and a manufacturing method thereof.

### Descriptions of the Related Art

Short-wave infrared (SWIR) light-emitting diodes typically have a wavelength range between 1100 nanometers (nm) and 2000 nm. This wavelength, being outside the visible light spectrum, is highly effective for penetrating smoke, fog, or certain materials, making it suitable for applications requiring penetration or detection of specific material absorption spectra. Commonly used SWIR wavelengths, such as 1050 nm, 1300 nm, and 1550 nm, can be optimized for various application needs. For instance, in medical devices, SWIR's ability to penetrate human skin has led to the development of application modules with built-in SWIR LEDs for vascular imaging, biological tissue analysis, and physiological monitoring.

However, most commercially available SWIR LEDs are vertical chip structures, without any horizontal chip structures available. Traditional vertical SWIR LEDs cannot meet the diverse packaging requirements of many application devices. Therefore, there is an urgent need in the industry for an innovative horizontal SWIR LED structure and manufacturing method to meet the development needs of subsequent application modules.

### SUMMARY OF THE INVENTION

The main objective of the present invention is to provide a high-brightness horizontal light-emitting diode and its manufacturing method, applicable to short-wave infrared (SWIR) LEDs with an emission wavelength range of 1100 to 2000 nanometers. In addition to providing a horizontal structure to enhance the flexibility of subsequent packaging module applications, the disclosed SWIR LED structure features a design that optimizes current distribution to improve brightness, thereby expanding the application scope of downstream products.

To achieve the above objective, the present invention provides a horizontal light-emitting diode comprising a permanent substrate, an epitaxial composite layer, a transparent conductive layer, a plurality of conductive plugs, a first conductive type electrode, and a second conductive type electrode. The epitaxial composite layer includes a light-emitting layer with an emission wavelength of 1100 to 2000 nanometers, disposed on the permanent substrate. The transparent conductive layer is sandwiched between the permanent substrate and the epitaxial composite layer. Each conductive plug is disposed between the transparent conductive layer and the epitaxial composite layer and is electrically connected to the epitaxial composite layer. The first conductive type electrode is disposed on the permanent substrate and is electrically connected to the epitaxial composite layer. The second conductive type electrode is disposed on the epitaxial composite layer, electrically connected to the epitaxial composite layer, and located on the same side of the permanent substrate as the first conductive type electrode.

In one embodiment of the horizontal light-emitting diode of the present invention, the epitaxial composite layer further comprises a first compound semiconductor layer and a second compound semiconductor layer, which sandwich the light-emitting layer, with the second compound semiconductor layer disposed between the light-emitting layer and the second conductive type electrode.

In one embodiment of the horizontal light-emitting diode of the present invention, the first compound semiconductor layer is a first conductive type indium phosphide (InP) layer, and the second compound semiconductor layer is a second conductive type indium phosphide (InP) layer.

In one embodiment of the horizontal light-emitting diode of the present invention, the horizontal light-emitting diode further comprises a dielectric layer, and the epitaxial composite layer further comprises a highly doped indium gallium arsenide phosphide (InGaAsP) layer, wherein each conductive plug is disposed in the dielectric layer, and the highly doped indium gallium arsenide phosphide layer is disposed between the first conductive type indium phosphide layer and the dielectric layer.

In one embodiment of the horizontal light-emitting diode of the present invention, each conductive plug is a metal stack forming an ohmic contact with the highly doped indium gallium arsenide phosphide layer, and the material of the metal stack is selected from the group consisting of titanium (Ti), platinum (Pt), gold (Au), palladium (Pd), germanium (Ge), zinc gold (ZnAu), and a combination thereof.

In one embodiment of the horizontal light-emitting diode of the present invention, the horizontal light-emitting diode further comprises a dielectric layer, with each conductive plug disposed in the dielectric layer.

In one embodiment of the horizontal light-emitting diode of the present invention, each conductive plug comprises a highly doped compound semiconductor layer and a metal stack, with the highly doped compound semiconductor layer sandwiched between the epitaxial composite layer and the metal stack, forming an ohmic contact with the metal stack.

In one embodiment of the horizontal light-emitting diode of the present invention, the highly doped compound semiconductor layer is a highly doped indium gallium arsenide phosphide (InGaAsP) layer.

In one embodiment of the horizontal light-emitting diode of the present invention, the material of the metal stack is selected from the group consisting of titanium (Ti), platinum (Pt), gold (Au), palladium (Pd), germanium (Ge), zinc gold (ZnAu), and a combination thereof.

In one embodiment of the horizontal light-emitting diode of the present invention, the permanent substrate is one of a silicon substrate and an aluminum nitride substrate.

To achieve the above objective, the present invention provides a manufacturing method for a horizontal light-emitting diode, comprising the following steps: forming an epitaxial composite layer on an epitaxial growth substrate, including a light-emitting layer with an emission wavelength of 1100 to 2000 nanometers; forming a transparent conductive layer sandwiched between the epitaxial growth substrate and the epitaxial composite layer; forming a plurality of conductive plugs disposed between the transparent conductive layer and the epitaxial composite layer, electrically connected to the epitaxial composite layer; forming a metal layer on the transparent conductive layer, bonding it to a permanent substrate wafer, and removing the epitaxial growth substrate; forming a first conductive type electrode on the permanent substrate, electrically connected to the epitaxial composite layer; and forming a second conductive type electrode on the epitaxial composite layer, electrically connected to the epitaxial composite layer, and located on the same side of the permanent substrate as the first conductive type electrode.

In one embodiment of the manufacturing method of the horizontal light-emitting diode of the present invention, the step of forming the epitaxial composite layer further comprises forming a first compound semiconductor layer and a second compound semiconductor layer, which sandwich the light-emitting layer, with the second compound semiconductor layer disposed between the light-emitting layer and the second conductive type electrode.

In one embodiment of the manufacturing method of the horizontal light-emitting diode of the present invention, the first compound semiconductor layer is a first conductive type indium phosphide (InP) layer, and the second compound semiconductor layer is a second conductive type indium phosphide (InP) layer.

In one embodiment of the manufacturing method of the horizontal light-emitting diode of the present invention, the method further comprises forming a dielectric layer, and the step of forming the epitaxial composite layer further comprises forming a highly doped indium gallium arsenide phosphide (InGaAsP) layer, wherein each conductive plug is disposed in the dielectric layer, and the highly doped indium gallium arsenide phosphide layer is disposed between the first conductive type indium phosphide layer and the dielectric layer.

In one embodiment of the manufacturing method of the horizontal light-emitting diode of the present invention, each conductive plug is a metal stack forming an ohmic contact with the highly doped indium gallium arsenide phosphide layer, and the material of the metal stack is selected from the group consisting of titanium (Ti), platinum (Pt), gold (Au), palladium (Pd), germanium (Ge), zinc gold (ZnAu), and a combination thereof.

In one embodiment of the manufacturing method of the horizontal light-emitting diode of the present invention, the method further comprises forming a dielectric layer, with each conductive plug disposed in the dielectric layer.

In one embodiment of the manufacturing method of the horizontal light-emitting diode of the present invention, each conductive plug comprises a highly doped compound semiconductor layer and a metal stack, with the highly doped compound semiconductor layer sandwiched between the epitaxial composite layer and the metal stack, forming an ohmic contact with the metal stack.

In one embodiment of the manufacturing method of the horizontal light-emitting diode of the present invention, the highly doped compound semiconductor layer is a highly doped indium gallium arsenide phosphide (InGaAsP) layer.

In one embodiment of the manufacturing method of the horizontal light-emitting diode of the present invention, the material of the metal stack is selected from the group consisting of titanium (Ti), platinum (Pt), gold (Au), palladium (Pd), germanium (Ge), zinc gold (ZnAu), and a combination thereof.

In one embodiment of the manufacturing method of the horizontal light-emitting diode of the present invention, the permanent substrate is one of a silicon substrate and an aluminum nitride substrate.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1A to FIG. 1H illustrate schematic diagrams of the manufacturing process of a horizontal light-emitting diode according to one embodiment of the present invention.

FIG. 2 is a schematic diagram of a horizontal light-emitting diode according to another embodiment of the present invention.

FIG. 3 is a schematic diagram of the process steps for manufacturing a horizontal light-emitting diode according to one embodiment of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

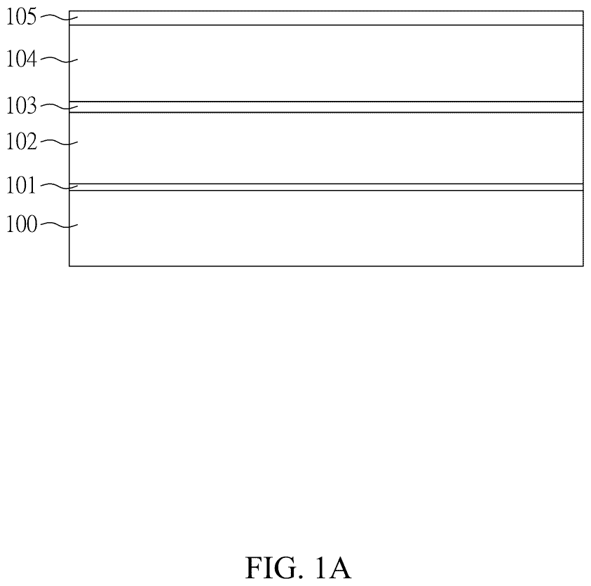

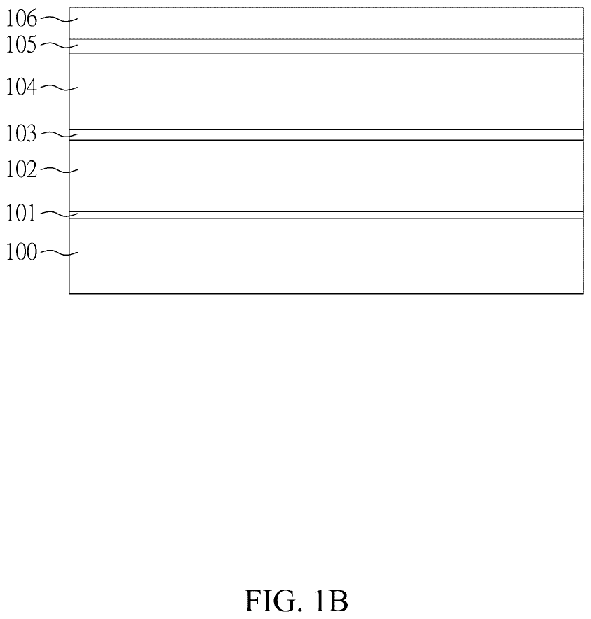

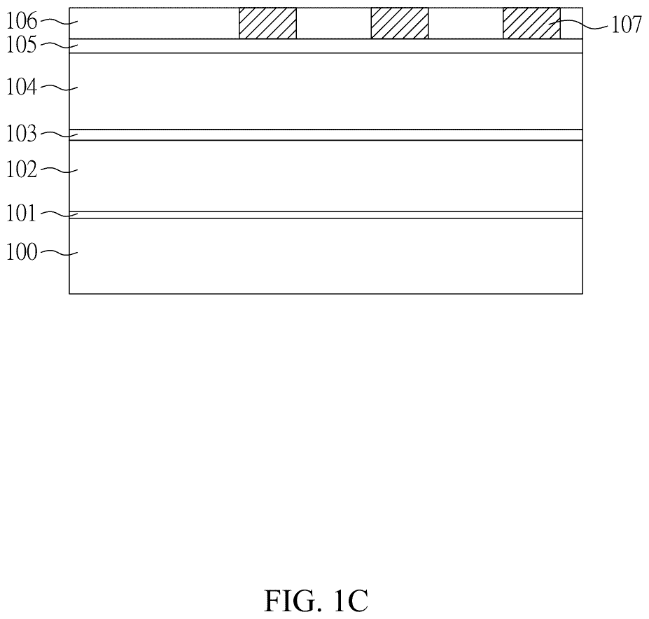

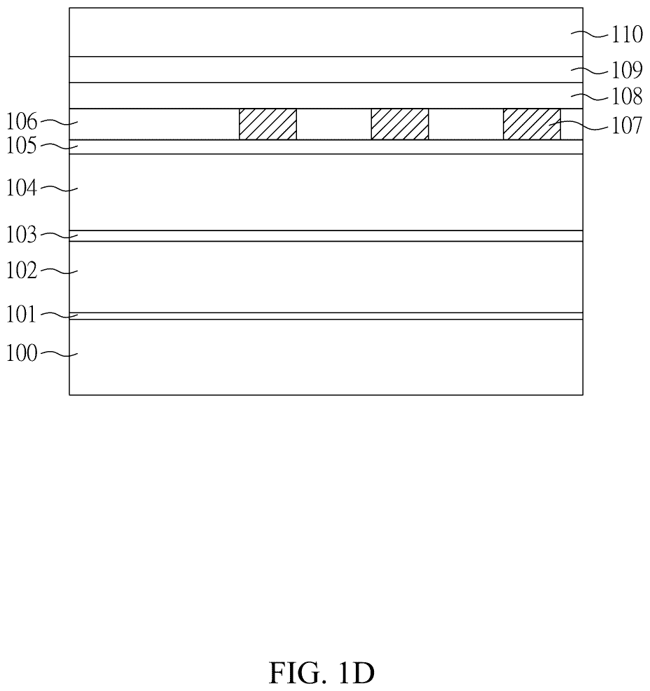

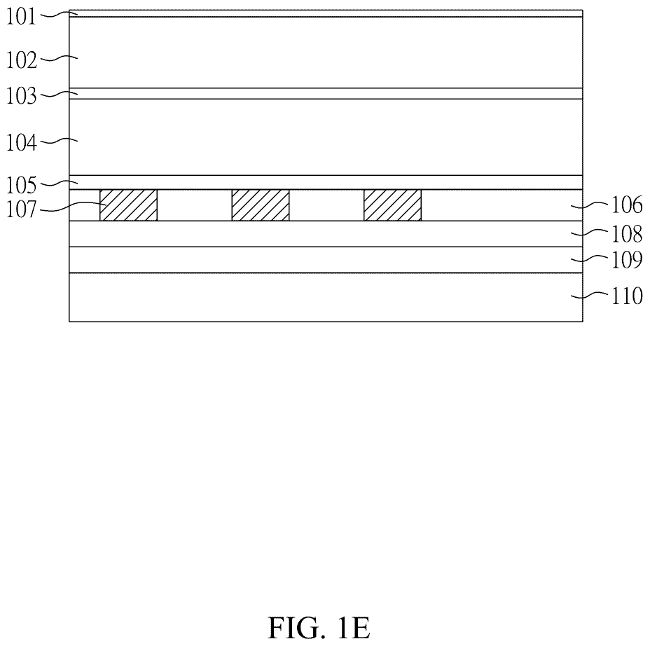

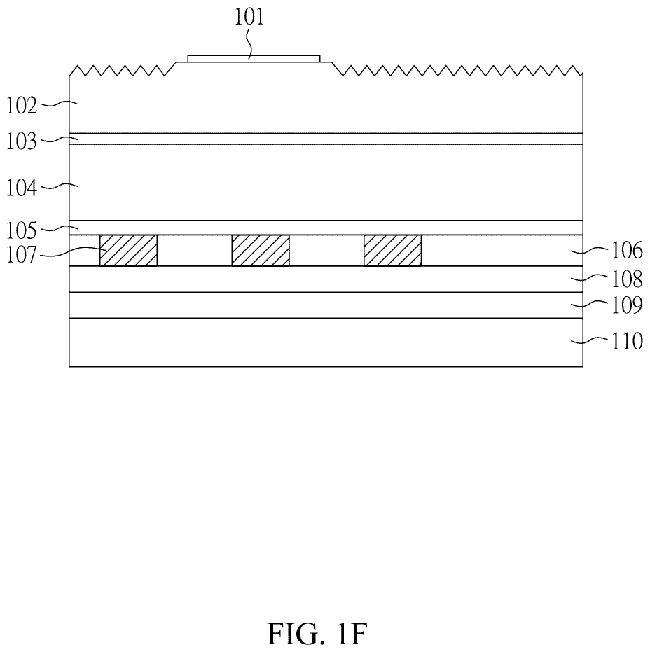

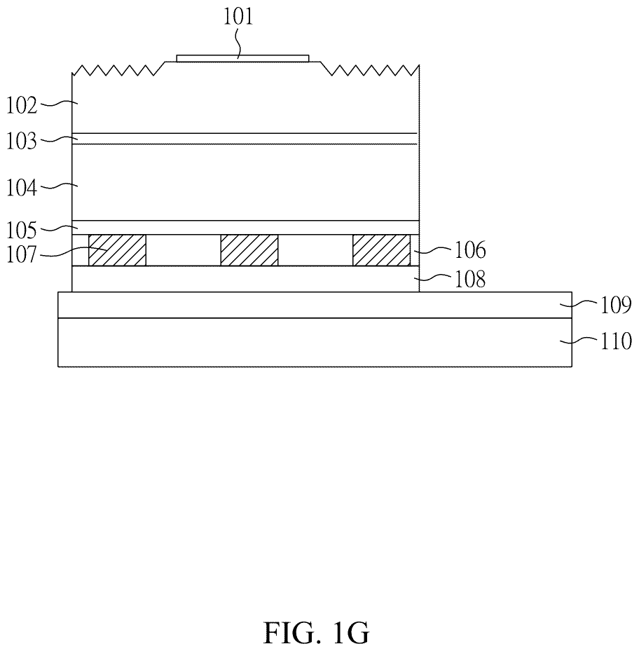

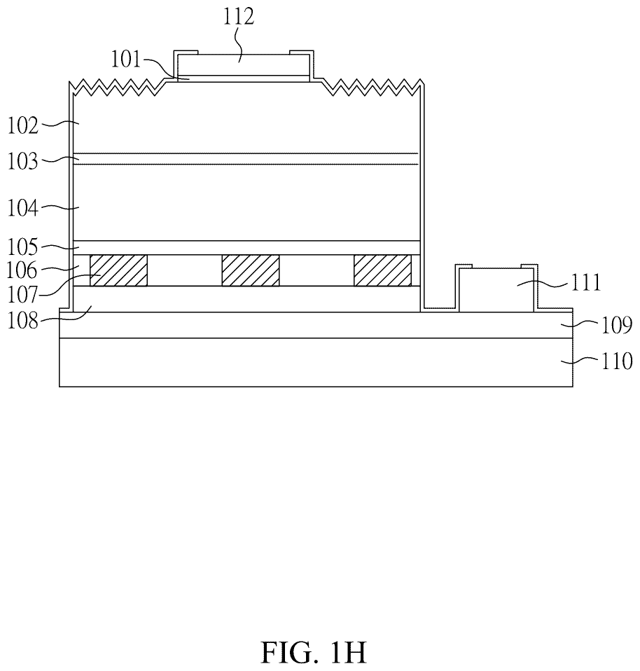

The present invention discloses a horizontal light-emitting diode and its manufacturing method. Referring to FIG. 1A, an epitaxial growth substrate 100, specifically an indium phosphide (InP) substrate though not limited thereto, is used to grow a buffer layer (not shown) and an N-type ohmic contact layer 101 using metal-organic chemical vapor deposition (MOCVD) or molecular beam epitaxy (MBE) techniques. The buffer layer, an N-type indium phosphide (InP) epitaxial layer, is used to adjust lattice matching between the epitaxial growth substrate and the subsequent epitaxial composite layer, reducing stress due to lattice mismatch in the subsequent epitaxial process, thereby improving the film quality of the subsequent epitaxial layers.

Next, the N-type ohmic contact layer 101 is specifically an N-type indium gallium arsenide (InGaAs) epitaxial layer, with a lattice constant between that of indium phosphide (InP) and a multiple quantum well structure. Thus, the N-type InGaAs epitaxial layer also serves as a buffer layer to further adjust lattice matching for subsequent epitaxial layers. Additionally, the N-type InGaAs layer optimizes carrier injection efficiency by adjusting its bandgap based on the gallium-to-indium ratio, controlling electron and hole transport to ensure more carriers are effectively injected into the light-emitting layer, enhancing luminous efficiency. Notably, the N-type ohmic contact layer 101 serves as the interface for ohmic contact with the N-type electrode. Common dopants in the N-type InGaAs layer include sulfur (S), selenium (Se), or silicon (Si), with doping concentrations typically ranging from 10¹⁸ to 10²⁰ cm⁻³. This concentration range helps reduce the Schottky barrier, achieving low-resistance ohmic contact.

Subsequently, an epitaxial composite layer is grown on the N-type ohmic contact layer 101, comprising a first compound semiconductor layer 104, a light-emitting layer 103, and a second compound semiconductor layer 102. The light-emitting layer 103 consists of a multiple quantum well (MQW) structure made of indium gallium arsenide phosphide (InGaAsP) quaternary compound semiconductor, sandwiched between the first compound semiconductor layer 104 and the second compound semiconductor layer 102. In this embodiment, the MQW emission wavelength ranges from 1100 to 2000 nanometers. Specifically, the first compound semiconductor layer 104 is a first conductive type (P-type) indium phosphide (InP) epitaxial layer, and the second compound semiconductor layer 102 is a second conductive type (N-type) indium phosphide (InP) epitaxial layer. It should be noted that the materials described in this embodiment are merely exemplary, and the invention is not limited thereto. In practical applications, the light-emitting layer may be a multiple quantum well (MQW) or double heterojunction (DH) structure, with materials and compositions adjusted based on the emission wavelength, such as indium aluminum gallium arsenide (InAlGaAs), indium gallium arsenide (InGaAs), indium gallium arsenide phosphide (InGaAsP), aluminum gallium phosphide (AlGaP), aluminum gallium indium phosphide (AlGaInP), indium arsenide antimonide (InAsSb), aluminum indium antimonide (InAlSb), or indium arsenide antimonide phosphide (InAsSbP).

As shown in FIG. 1A, a compound semiconductor layer is further epitaxially grown on the epitaxial composite layer. In this embodiment, this layer is a highly doped indium gallium arsenide phosphide (InGaAsP) layer 105 used as an ohmic contact layer, such as, but not limited to, a zinc-doped InGaAsP epitaxial layer, with a preferred thickness of 500 to 5000 angstroms (Å). Specifically, the doping concentration of this zinc-doped InGaAsP layer ranges from 10¹⁸ to 10²⁰ cm⁻³, which helps reduce contact resistance to form an ohmic contact with the subsequent metal layer interface.

Next, referring to FIG. 1B, a dielectric layer 106 is deposited to cover the entire wafer surface, followed by a photolithography and etching process to pattern and remove portions of the dielectric layer 106. Specifically, the dielectric layer 106 may be made of silicon dioxide (SiO₂), silicon nitride (Si₃N₄), silicon oxynitride (SiON), or similar materials. The pattern of the dielectric layer 106 is determined based on the layout of the conductive plugs to be formed subsequently. As shown in FIG. 1C, a metal stack 107 is deposited between the patterned dielectric layer 106 using evaporation or sputtering to form multiple conductive plugs on the surface of the highly doped indium gallium arsenide phosphide (InGaAsP) layer 105, creating an ohmic contact at their interface. The metal stack 107 may specifically be selected from the group consisting of titanium (Ti), platinum (Pt), gold (Au), palladium (Pd), germanium (Ge), zinc gold (ZnAu), and a combination thereof, with a thickness less than 1 micrometer, preferably 2000 to 5000 angstroms (Å). The pattern design of these conductive plugs is primarily intended to guide the vertical current in the LED chip to distribute uniformly across the crystal structure, reducing current crowding and thereby enhancing luminous efficiency.

Next, referring to FIG. 1D, a transparent conductive layer 108 is formed on the wafer surface by evaporation or sputtering, covering the dielectric layer 106 and the metal stacks 107 within the dielectric layer 106, and electrically connecting to the metal stacks 107 of the conductive plugs. The transparent conductive layer 108 is made of materials such as indium tin oxide (ITO), aluminum zinc oxide (AZO), indium zinc oxide (IZO), nickel oxide, cadmium tin oxide, antimony tin oxide, or a combination thereof. Subsequently, a reflective metal layer 109 is formed on the transparent conductive layer 108 by evaporation, followed by wafer bonding with another permanent substrate 110. The transparent conductive layer 108 and reflective metal layer 109 serve as a mirror system in the LED structure to reflect light emitted from the light-emitting layer upward, enhancing light extraction efficiency. The reflective metal layer is made of materials selected from the group consisting of silver (Ag), titanium (Ti), platinum (Pt), gold (Au), indium (In), and a combination thereof. The permanent substrate 110 may be, but not limited to, a silicon substrate or an aluminum nitride (AlN) substrate.

Referring to FIG. 1E, the epitaxial growth substrate 100 and buffer layer are removed from the other side of the permanent substrate 110, exposing the N-type ohmic contact layer 101, and the wafer is flipped so that the permanent substrate 110 is at the bottom of the horizontal LED structure. Next, a patterned etching process is performed on the N-type ohmic contact layer 101 to remove portions of it, retaining only the areas intended for the upper electrode. Then, the exposed surface of the second compound semiconductor layer 102, i.e., the N-type indium phosphide (InP) epitaxial layer, is roughened, as shown in FIG. 1F.

Subsequently, referring to FIG. 1G, a mesa etching process is performed to etch portions of the epitaxial composite layer, dielectric layer 106, and transparent conductive layer 108, specifically etching parts of the second compound semiconductor layer 102, light-emitting layer 103, first compound semiconductor layer 104, dielectric layer 106, and transparent conductive layer 108, exposing a flat surface of the reflective metal layer 109 for disposing the lower electrode in the subsequent process.

Referring to FIG. 1H, a metal evaporation process is performed to form the first conductive type electrode 111 on the permanent substrate 110, electrically connected to the reflective metal layer 109. On the other hand, the second conductive type electrode 112 is formed on the N-type ohmic contact layer 101, creating an ohmic contact with it and electrically connecting to the epitaxial composite layer. The first conductive type electrode 111 and second conductive type electrode 112 may be, for example, but not limited to, a metal stack of germanium-titanium (GeTi) alloy, platinum (Pt), or gold (Au). Finally, a protective layer is formed over the device surface, excluding the upper and lower electrode surfaces, completing the final structure of the horizontal SWIR LED of the present invention. This device is characterized by having both positive and negative electrodes on the same side, providing greater design flexibility for downstream application modules. Moreover, the layout design of the conductive plugs in the horizontal SWIR LED enhances the uniformity of vertical current distribution within the device, improving its luminous efficiency.

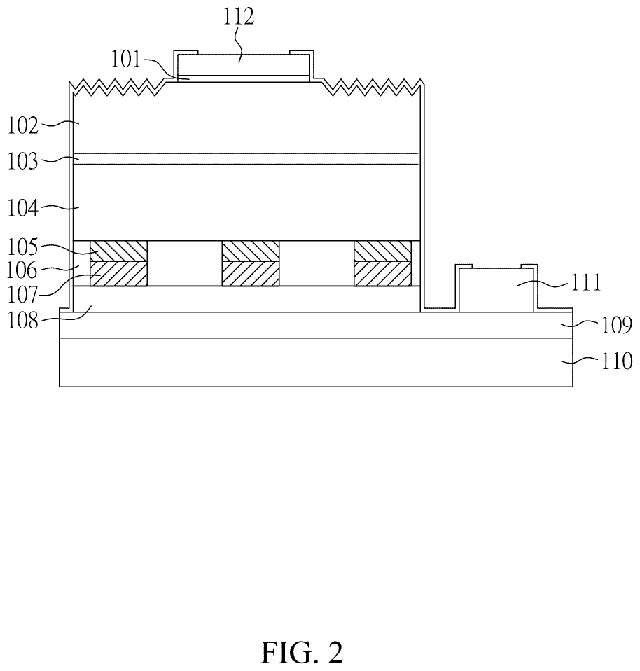

As shown in FIG. 2, a cross-sectional schematic diagram of a horizontal SWIR LED according to another embodiment of the present invention is presented. Unlike the previous embodiment, the conductive plugs in this embodiment have a dual-layer structure, comprising a patterned highly doped indium gallium arsenide phosphide (InGaAsP) layer 105 and a metal stack 107. In contrast to the LED in FIG. 1H, which has a complete, continuous highly doped InGaAsP layer 105, the InGaAsP layer 105 in the LED of FIG. 2 is not a continuous layer but is patterned and integrated into each independent conductive plug. Since the highly doped InGaAsP layer absorbs short-wave infrared light in the 1100 to 2000 nm range, the LED in this embodiment specifically patterns the entire layer to integrate it into the conductive plug structure, reducing its overall area. This balances the considerations of ohmic contact and light absorption, further enhancing the device's luminous efficiency.

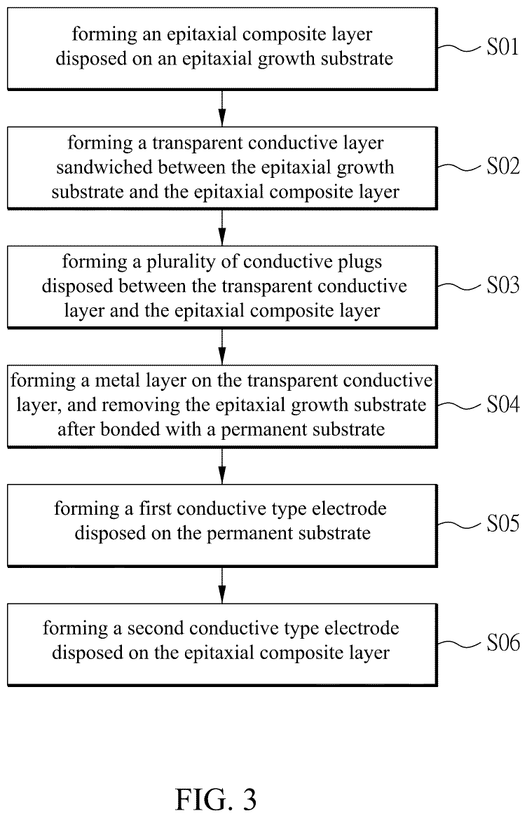

Referring to FIG. 3, a schematic flowchart of the manufacturing process for the horizontal light-emitting diode of the present invention is shown. First, in step S01, an epitaxial composite layer is formed on an epitaxial growth substrate, including a light-emitting layer with an emission wavelength of 1100 to 2000 nanometers. In step S02, a transparent conductive layer is formed, sandwiched between the epitaxial growth substrate and the epitaxial composite layer. Next, in step S03, multiple conductive plugs are formed between the transparent conductive layer and the epitaxial composite layer, electrically connected to the epitaxial composite layer. In step S04, a metal layer is formed on the transparent conductive layer, bonded to a permanent substrate wafer, and the epitaxial growth substrate is removed. In step S05, a first conductive type electrode is formed on the permanent substrate, electrically connected to the epitaxial composite layer. Finally, in step S06, a second conductive type electrode is formed on the epitaxial composite layer, electrically connected to the epitaxial composite layer, and located on the same side of the permanent substrate as the first conductive type electrode. Details of the components in the aforementioned process steps can be referred to above and are not repeated here.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A horizontal light-emitting diode, comprising:
a permanent substrate;
an epitaxial composite layer, including a light-emitting layer with an emission wavelength of 1100 to 2000 nanometers disposed on the permanent substrate;
a transparent conductive layer, sandwiched between the permanent substrate and the epitaxial composite layer;
a plurality of conductive plugs, disposed between the transparent conductive layer and the epitaxial composite layer and electrically connected to the epitaxial composite layer;
a first conductive type electrode, disposed on the permanent substrate and electrically connected to the epitaxial composite layer; and
a second conductive type electrode disposed on the epitaxial composite layer, electrically connected to the epitaxial composite layer and located on the same side of the permanent substrate as the first conductive type electrode.

2. The horizontal light-emitting diode of claim 1, wherein the epitaxial composite layer further comprises a first compound semiconductor layer and a second compound semiconductor layer, the first compound semiconductor layer and the second compound semiconductor layer sandwich the light-emitting layer, and the second compound semiconductor layer is disposed between the light-emitting layer and the second conductive type electrode.

3. The horizontal light-emitting diode of claim 2, wherein the first compound semiconductor layer is a first conductive type indium phosphide (InP) layer, and the second compound semiconductor layer is a second conductive type indium phosphide (InP) layer.

4. The horizontal light-emitting diode of claim 3, further comprising a dielectric layer, and the epitaxial composite layer further comprises a highly doped indium gallium arsenide phosphide (InGaAsP) layer, wherein each of the conductive plugs is disposed in the dielectric layer, and the highly doped indium gallium arsenide phosphide layer is disposed between the first conductive type indium phosphide layer and the dielectric layer.

5. The horizontal light-emitting diode of claim 4, wherein each of the conductive plugs is a metal stack, forming an ohmic contact with the highly doped indium gallium arsenide phosphide layer, and the material of the metal stack is selected from the group consisting of titanium (Ti), platinum (Pt), gold (Au), palladium (Pd), germanium (Ge), zinc gold (ZnAu) and a combination thereof.

6. The horizontal light-emitting diode of claim 3, further comprising a dielectric layer and each of the conductive plugs is disposed in the dielectric layer.

7. The horizontal light-emitting diode of claim 6, wherein each of the conductive plugs comprises a highly doped compound semiconductor layer and a metal stack, and the highly doped compound semiconductor layer is sandwiched between the epitaxial composite layer and the metal stack and forms an ohmic contact with the metal stack.

8. The horizontal light-emitting diode of claim 7, wherein the highly doped compound semiconductor layer is a highly doped indium gallium arsenide phosphide (InGaAsP) layer.

9. The horizontal light-emitting diode of claim 7, wherein the material of the metal stack is selected from the group consisting of titanium (Ti), platinum (Pt), gold (Au), palladium (Pd), germanium (Ge), zinc gold (ZnAu) and a combination thereof.

10. The horizontal light-emitting diode of claim 1, wherein the permanent substrate is one of a silicon substrate and an aluminum nitride substrate.

11. A manufacturing method of a horizontal light-emitting diode, comprising:
forming an epitaxial composite layer, disposed on an epitaxial growth substrate, including a light-emitting layer with an emission wavelength of 1100 to 2000 nanometers;
forming a transparent conductive layer, sandwiched between the epitaxial growth substrate and the epitaxial composite layer;
forming a plurality of conductive plugs, disposed between the transparent conductive layer and the epitaxial composite layer and electrically connected to the epitaxial composite layer;
forming a metal layer on the transparent conductive layer, and removing the epitaxial growth substrate after bonding the epitaxial growth substrate to a permanent substrate;
forming a first conductive type electrode, disposed on the permanent substrate and electrically connected to the epitaxial composite layer; and
forming a second conductive type electrode disposed on the epitaxial composite layer, electrically connected to the epitaxial composite layer and located on the same side of the permanent substrate as the first conductive type electrode.

12. The manufacturing method of a horizontal light-emitting diode of claim 11, wherein the step of forming an epitaxial composite layer further comprises to form a first compound semiconductor layer and a second compound semiconductor layer, the first compound semiconductor layer and the second compound semiconductor layer sandwich the light-emitting layer, and the second compound semiconductor layer is disposed between the light-emitting layer and the second conductive type electrode.

13. The manufacturing method of a horizontal light-emitting diode of claim 12, wherein the first compound semiconductor layer is a first conductive type indium phosphide (InP) layer, and the second compound semiconductor layer is a second conductive type indium phosphide (InP) layer.

14. The manufacturing method of a horizontal light-emitting diode of claim 13, further comprising to form a dielectric layer, and the step of forming the epitaxial composite layer further comprises a step of forming a highly doped indium gallium arsenide phosphide (InGaAsP) layer, wherein each of the conductive plugs is disposed in the dielectric layer, and the highly doped indium gallium arsenide phosphide layer is disposed between the first conductive type indium phosphide layer and the dielectric layer.

15. The manufacturing method of a horizontal light-emitting diode of claim 14, wherein each of the conductive plugs is a metal stack, forming an ohmic contact with the highly doped indium gallium arsenide phosphide layer, and the material of the metal stack is selected from the group consisting of titanium (Ti), platinum (Pt), gold (Au), palladium (Pd), germanium (Ge), zinc gold (ZnAu) and a combination thereof.

16. The manufacturing method of a horizontal light-emitting diode of claim 13, further comprising to form a dielectric layer and each of the conductive plugs is disposed in the dielectric layer.

17. The manufacturing method of a horizontal light-emitting diode of claim 16, wherein each of the conductive plugs comprises a highly doped compound semiconductor layer and a metal stack, and the highly doped compound semiconductor layer is sandwiched between the epitaxial composite layer and the metal stack and forms an ohmic contact with the metal stack.

18. The manufacturing method of a horizontal light-emitting diode of claim 17, wherein the highly doped compound semiconductor layer is a highly doped indium gallium arsenide phosphide (InGaAsP) layer.

19. The manufacturing method of a horizontal light-emitting diode of claim 17, wherein the material of the metal stack is selected from the group consisting of titanium (Ti), platinum (Pt), gold (Au), palladium (Pd), germanium (Ge), zinc gold (ZnAu) and a combination thereof.

20. The manufacturing method of a horizontal light-emitting diode of claim 11, wherein the permanent substrate is one of a silicon substrate and an aluminum nitride substrate.
